(19) United States
(12) Patent Application Publication
(10) Pub. No.: US 2013/0175570 A1
(43) Pub. Date: Jul. 11, 2013

(54) LED Lamp

(71) Applicant: Wen-Lung Chin, New Taipei City (TW)

(72) Inventor: Wen-Lung Chin, New Taipei City (TW)

(21) Appl. No.: 13/344,641

(22) Filed: Jan. 6, 2012

(51) Int. Cl. H01L 33/64

(52) U.S. Cl. 257/99; 257/E33.075

(57) ABSTRACT

An LED lamp includes a housing, and a base plate combined with the housing. The base plate is integrally combined with the housing by injection molding so that the base plate and the housing are combined closely and solidly and will not detach from each other.

### BACKGROUND OF THE INVENTION

1. Field of the Invention

The present invention relates to a lighting appliance and, more particularly, to an LED (light emitting diode) lamp.

2. Description of the Related Art

A conventional LED (light emitting diode) lamp comprises a housing, and a base plate combined with the housing. The base plate is combined with an LED module (which is a modularized product) so that the base plate and the LED module are packed to function as an LED light source. Alternatively, the base plate is combined with at least one LED crystal so that the base plate and the LED crystal are packed to function as an LED light source. The base plate has a plurality of screw holes, and the housing has a plurality of screw bores which are connected with the screw holes of the base plate by a plurality of screw members so that the base plate is combined with the housing by screwing. However, the base plate is not combined with the housing closely and tightly by screwing, thereby decreasing the structural strength of the LED lamp. Alternatively, the base plate is combined with the housing by a bonding agent, such as a gel and the like. However, the bonding agent is located between the base plate and the housing, thereby decreasing the heat conducting effect of the LED lamp.

### BRIEF SUMMARY OF THE INVENTION

In accordance with the present invention, there is provided an LED lamp, comprising a housing, and a base plate combined with the housing. The base plate is integrally combined with the housing by injection molding.

Preferably, the base plate is made of a nonmetallic material having a porous structure with great heat conduction and dissipation effects, and the housing is made of a plastic material.

Preferably, the base plate is made of a metal having great heat conductivity, and the housing is made of a plastic material.

Preferably, the base plate is made of a nonmetallic material having a porous structure with great heat conduction effect, and the housing is made of a nonmetallic material having a porous structure with great heat dissipation effect.

Preferably, the LED lamp further comprises a heatsink module combined with the housing.

Preferably, the heatsink module is integrally combined with the housing by injection molding.

Preferably, the base plate, the housing and the heatsink module are integrally combined together by injection molding.

Preferably, the heatsink module is located under the base plate and has a top face abutting a bottom face of the base plate.

The primary objective of the present invention is to provide an LED lamp having a better structural strength.

According to the primary advantage of the present invention, the base plate is integrally combined with the housing completely by injection molding so that the base plate and the housing are combined closely and solidly and will not detach from each other so as to enhance the structural strength of the LED lamp.

According to another advantage of the present invention, the base plate and the housing are combined closely so as to enhance the heat conducting effect of the LED lamp.

Further benefits and advantages of the present invention will become apparent after a careful reading of the detailed description with appropriate reference to the accompanying drawings.

### BRIEF DESCRIPTION OF THE SEVERAL VIEWS OF THE DRAWING(S)

FIG. 1 is a front cross-sectional assembly view of an LED lamp in accordance with the preferred embodiment of the present invention.

### DETAILED DESCRIPTION OF THE INVENTION

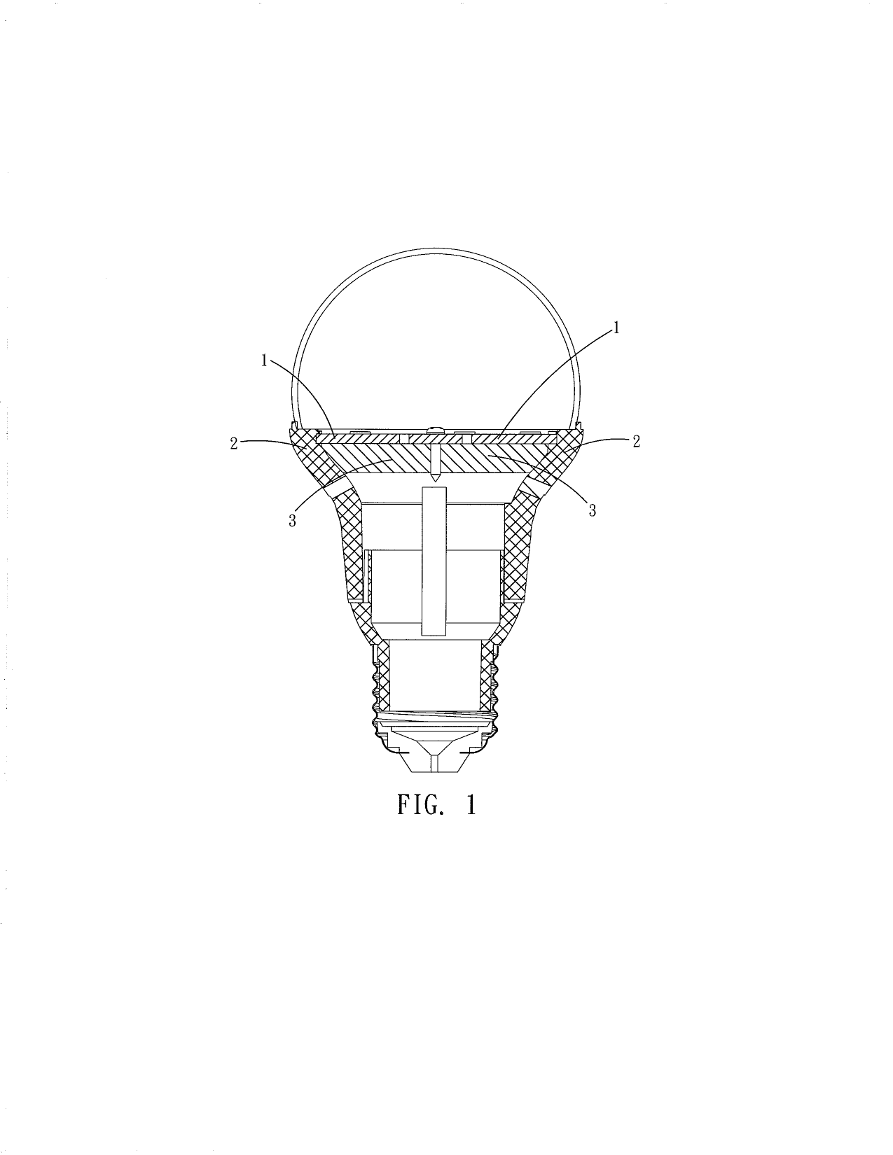

Referring to FIG. 1, an LED (light emitting diode) lamp in accordance with the preferred embodiment of the present invention comprises a housing 2, and a base plate 1 combined with the housing 2. The base plate 1 is integrally combined with the housing 2 by plastic injection molding. The base plate 1 is combined with an LED module (which is a modularized product) so that the base plate 1 and the LED module are packed to function as an LED light source. Alternatively, the base plate 1 is combined with at least one LED crystal so that the base plate 1 and the LED crystal are packed to function as an LED light source.

In fabrication, the base plate 1 is initially formed and worked. For example, the base plate 1 is flattened and drilled in the working process. Then, the base plate 1 is placed in a die cavity of an injection molding machine. Then, the housing 2 covers the base plate 1 during an injection molding process so that the base plate 1 is integrally combined with the housing 2 by injection molding. Thus, the base plate 1 is integrally combined with the housing 2 by plastic injection molding so that the base plate 1 and the housing 2 are combined closely and solidly and will not detach from each other so as to enhance the structural strength of the LED lamp.

In the preferred embodiment of the present invention, the base plate 1 is made of a metal having great heat conductivity and great heat dissipation, such as gold, silver, copper, iron, aluminum, cobalt, nickel, zinc, titanium, manganese and the like. Alternatively, the base plate 1 is made of a nonmetallic material having a porous structure with great heat conduction and dissipation effects. The porous nonmetallic material of the base plate 1 is made of a nonmetallic powder having a great heat conductivity, such as Al₂O₃, Zr₂O, AlN, SiN, BN, WC, SiC, C, crystalline SiC, Recrystalline SiC (ReSiC) and the like. Preferably, the nonmetallic powder of the base plate 1 is selected by AlN and SiC.

In the preferred embodiment of the present invention, the housing 2 is made of a plastic material. Alternatively, the housing 2 is made of a nonmetallic material having a porous structure with great heat conduction and dissipation effects. The porous nonmetallic material of the housing 2 is made of a nonmetallic powder having a great heat conductivity, such as Al₂O₃, Zr₂O, SiN, BN, WC, SiC, C, crystalline SiC, Recrystalline SiC (ReSiC) and the like. Preferably, the nonmetallic powder of the base plate 1 is selected by AlN and SiC.

In the preferred embodiment of the present invention, the LED lamp further comprises a heatsink module 3 combined with the housing 2. The heatsink module 3 is integrally combined with the housing 2 by injection molding. Thus, the base plate 1, the housing 2 and the heatsink module 3 are integrally combined together by injection molding. The heatsink module 3 is located under the base plate 1 and has a top face abutting a bottom face of the base plate 1 to enhance the heatsink effect of the base plate 1.

In the preferred embodiment of the present invention, the housing 2 has an end portion provided with a threaded stud for mounting a metallic screw base, an insulating gasket and a power contact plate. Preferably, each of the metallic screw base, the insulating gasket and the power contact plate has an international specification of E-27, E-14 and the like so that the housing 2 is available for a conventional electric bulb.

Alternatively, the housing 2 is provided with two connecting pins (with an international specification of MR16 and the like) so that the housing 2 is available for a conventional projection lamp.

Accordingly, the base plate 1 is integrally combined with the housing 2 completely by injection molding so that the base plate 1 and the housing 2 are combined closely and solidly and will not detach from each other so as to enhance the structural strength of the LED lamp. In addition, the base plate 1 and the housing 2 are combined closely so as to enhance the heat conducting effect of the LED lamp.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

1: An LED lamp, comprising:
a housing; and
a base plate combined with the housing;
wherein the base plate is an integral injection molding combined with the housing; and
the base plate is received in and covered by the housing.

2: The LED lamp of claim 1, wherein
the base plate is made of a nonmetallic material having a porous structure with great heat conduction and dissipation effects;
the housing is made of a plastic material.

3: The LED lamp of claim 1, wherein
the base plate is made of a metal having great heat conductivity;
the housing is made of a plastic material.

4: The LED lamp of claim 1, wherein
the base plate is made of a nonmetallic material having a porous structure with great heat conduction effect;
the housing is made of a nonmetallic material having a porous structure with great heat dissipation effect.

5: The LED lamp of claim 1, wherein the LED lamp further comprises a heatsink module combined with the housing and abutting the base plate.

6: The LED lamp of claim 5, wherein the heatsink module is an integral injection molding combined with the housing.

7: The LED lamp of claim 5, wherein the base plate, the housing and the heatsink module are an integral injection molding combined together.

8: The LED lamp of claim 5, wherein the heatsink module is located under the base plate and has a top face abutting a bottom face of the base plate.

9: The LED lamp of claim 5, wherein the heatsink module is received in and covered by the housing.

10: The LED lamp of claim 5, wherein the heatsink module is enclosed between the housing and the base plate.
